(19) United States
(12) Patent Application Publication
(10) Pub. No.: US 2010/0025786 A1
(43) Pub. Date: Feb. 4, 2010

(54) Method for Manufacturing a Diaphragm on a Semiconductor Substrate and Micromechanical Component Having Such a Diaphragm

(76) Inventors: Peter Schmollngruber, Aidlingen (DE); Hans Artmann, Boeblingen-Dagersheim (DE); Thomas Wagner, Stuttgart (DE); Heribert Weber, Nuertingen (DE)

Correspondence Address: KENYON & KENYON LLP, ONE BROADWAY, NEW YORK, NY, 10004, US

(21) Appl. No.: 12/086,951

(22) PCT Filed: Nov. 15, 2006
(86) PCT No.: PCT/EP2006/068514

§ 371 Date: Apr. 27, 2009

(30) Foreign Application Priority Data
Dec. 20, 2005 (DE) 10 2005 060 872.8
Jan. 11, 2006 (DE) 10 2006 001 386.7

(51) Int. Cl. H01L 29/84; H01L 21/30

(52) U.S. Cl. 257/419; 438/53; 257/E29.324; 257/E21.211

(57) ABSTRACT

A method for manufacturing a diaphragm, on a semiconductor substrate, includes the method operations or tasks of a) providing a semiconductor substrate, b) producing trenches in the semiconductor substrate, webs made of semiconductor substrate remaining between the trenches, c) producing an oxide layer on the walls of the trenches with the aid of a thermal oxidation method, d) producing access openings in a cover layer produced in a preceding method operation or task on the semiconductor substrate, to expose the semiconductor substrate in the area of the webs, e) isotropic etching of the semiconductor substrate exposed in method operation or task d) using a method selective to the oxide layer and to the cover layer, at least one cavity being produced in the webs below the cover layer, which is laterally delimited by the oxide layer of at least one trench, and f) depositing a sealing layer to seal the access openings in the cover layer.

### FIELD OF THE INVENTION

The present invention relates to a method for manufacturing a freestanding diaphragm on a semiconductor substrate. Furthermore, the present invention relates to a micromechanical component having such a diaphragm, such as a micromechanical sensor.

### BACKGROUND INFORMATION

Freestanding diaphragms may be used in various micromechanical components, such as sensor components of pressure or mass flow sensors. Depending on the application and measuring principle used, different requirements apply to the particular diaphragm.

In particular mechanical sensors which are based on thermal measuring principles, such as mass flow sensors, require good thermal insulation of their heating elements and temperature probes. For this purpose, freestanding diaphragms are currently used, which are manufactured in so-called bulk micromechanics. In this method, the silicon is etched through the entire wafer. The manufacturing of such dielectric diaphragms using surface mount technology (SMT) offers great advantages in the production of sensor chips and in the subsequent construction and connection technology. In particular supported dielectric diaphragms which have been produced using SMT technology are distinguished by their great potential in regard to mechanical stability and good thermal insulation. To achieve good thermal insulation, cavities which are as deep as possible having support structures of low wall thickness must be formed. Simultaneously, the actual diaphragm layer is to be kept as thin as possible.

Various methods are already known for manufacturing such diaphragms.

Thus, DE 101 303 79 A1, for example, discusses a manufacturing method in which diaphragms are produced on solid oxidized columns. Because of the support structures implemented as solid oxide columns, the diaphragms thus manufactured still have a comparatively high thermal conductivity to the substrate, however.

Technologies for manufacturing diaphragm sensors, in which the diaphragm is supported by oxidic hollow columns, are discussed in DE 103 520 01 A1. The significantly lower wall thicknesses of the hollow support structures cause less heat transport and thus improved thermal insulation between the diaphragm and the substrate. However, in this method, in which the support structures are produced within a layer stack situated on the substrate, the design freedom is greatly restricted. Thus, in particular the depth of the cavities is limited by the layer thickness of the layer stack. Furthermore, the opening width is not independent of the trench depth, and two sealing layers are required to hermetically close the cavities again.

Furthermore, a method is discussed in DE 101 448 47 A1, in which a diaphragm is manufactured on solid oxide columns. The columns are produced by deposition of a dielectric material in trenches previously structured in the substrate. The substrate is subsequently etched back below the diaphragm. The thermal insulation of the diaphragm layer from the substrate is limited because of the solid oxide columns, however.

### SUMMARY OF THE INVENTION

It is an object of the exemplary embodiments and/or exemplary methods of the present invention to provide a manufacturing method for a diaphragm on semiconductor substrates which has particularly good thermal insulation. Furthermore, it is an object of the exemplary embodiments and/or exemplary methods of the present invention to provide a micromechanical component having such a diaphragm.

This object may be achieved by a method for manufacturing a diaphragm on a semiconductor substrate as described herein. Furthermore, the object may be achieved by a micromechanical component as described herein. Further advantageous embodiments, designs, and aspects of the exemplary embodiments and/or exemplary methods of the present invention are also described herein.

The method according to the present invention is based on a combination of deep trenching and gas-phase etching to manufacture a hollow space forming a cavity below a diaphragm.

This is achieved according to the exemplary embodiments and/or exemplary methods of the present invention in that in a first method step, trenches are first produced in a provided semiconductor substrate (trenching). Webs made of semiconductor substrate remain standing between the trenches. An oxide layer is next produced with the aid of a thermal oxidation method on the walls of the trenches. Access openings are subsequently etched in a cover layer produced on the semiconductor substrate in a prior method step, to expose the semiconductor substrate in the area of the webs. At least one cavity is produced below the cover layer in the semiconductor webs by isotropic etching of the exposed semiconductor substrate in the area of the access openings. The etching is performed using a method selective to the oxide layer and to the cover layer, so that the resulting cavity is laterally delimited by the oxide layer of at least one trench. Finally, a sealing layer is deposited, to close the access openings in the cover layer again. This method particularly has the advantage that the support structures thus produced have a very low wall thickness. This causes particularly good thermal insulation of the diaphragm from the substrate.

In an exemplary embodiment of the present invention, the oxide layer is produced in that a semiconductor substrate is deposited on the walls of the trenches and subsequently thermally oxidized, the diameter of the trench opening being reduced and the aspect ratio of the trench being increased upon deposition of the semiconductor layer. This method has the advantage in particular that the opening width of the trenches on the surface may be made largely independent of the depth of the trenches in particular. The sealing layer required for the diaphragm may thus also be designed as comparatively thin. This has a positive effect on the heat conduction of the diaphragm because in particular lateral heat conduction is reduced with the thickness of the diaphragm layer. Furthermore, a thinner sealing layer also has a positive effect on the heat capacity of the diaphragm.

In another exemplary embodiment of the present invention, the semiconductor layer is deposited and subsequently oxidized also on the surface of the semiconductor substrate in the area of the webs. In the area of the webs, the oxidized semiconductor layer subsequently forms the cover layer for the structuring of the access openings. The process is thus simplified, because no additional cover layer has to be deposited.

In a particular variant of the exemplary embodiments and/or exemplary methods of the present invention, the trenches are constricted upon deposition of the semiconductor layer, so that a gap having a small opening width remains in the trenches, a hollow oxide column being produced in the interior of each of the trenches upon subsequent oxidation of the semiconductor layer. The narrow opening width of the trenches has the advantage that the sealing layer required for closing the trench openings may be particularly thin. The thermal conductivity and/or the heat capacity of the diaphragm may thus be reduced.

In an exemplary embodiment of the present invention, the trenches are constricted upon deposition of the semiconductor layer, so that a narrow gap remains in each of the trenches, which completely fills up with oxide upon the subsequent oxidation of the semiconductor layer, a thin, solid oxide column being produced in the interior of each of the trenches. The oxide columns produced in this way have a very small diameter. The thermal insulation of the diaphragm from the substrate is thus improved.

In further exemplary embodiments of the present invention, polysilicon or germanium is used as the semiconductor layer. The semiconductor layer thus produced is also etched when etching back the silicon substrate to produce a cavity in the webs. The polysilicon or the germanium is advantageously deposited using an LPCVD method. This method is particularly suitable for applying a thin polysilicon or germanium layer to the walls of a trench.

In a particular variant of the exemplary embodiments and/or exemplary methods of the present invention, the trenches are produced in the semiconductor substrate using a hard mask. This hard mask subsequently forms the cover layer. Because the opening width in the hard mask is typically smaller than that of the trenches produced underneath, a relatively thin sealing layer suffices to close the openings. This has a positive effect in turn on the heat conduction and the heat capacity of the diaphragm.

In an exemplary embodiment of the present invention, the oxide layer is produced by thermally oxidizing the semiconductor substrate on the walls of the trenches produced using the hard mask layer. Because the deposition of an additional semiconductor layer is dispensed with in this case, the process complexity is reduced.

In a further exemplary embodiment of the present invention, the access openings produced in the cover layer have an essentially identical diameter as the trench openings. Closing the access openings and the trench openings is thus simplified. The layer thickness required for closing the openings is optimized.

In a further specific embodiment of the present invention, after an oxide layer is produced and before access openings are produced, a sacrificial layer is deposited, the trenches being completely sealed, and the sacrificial layer is removed again during the isotropic etching. With the aid of the sacrificial layer, it is ensured that a subsequent lacquering process using photoresist may be performed homogeneously.

In the following, the exemplary embodiments and/or exemplary methods of the present invention is explained in greater detail on the basis of the drawings.

### BRIEF DESCRIPTION OF THE DRAWINGS

FIGS. 1A, 1B, 1C and 1D show the method steps of a method according to the present invention for manufacturing a diaphragm on a semiconductor substrate having hollow support structures.

FIGS. 2A, 2B and 2C show the method operations or tasks of a second variant of the method according to the present invention for manufacturing a diaphragm on a semiconductor substrate having solid support structures.

FIGS. 3A, 3B, 3C, 3D and 3E show the method operations or tasks of a third variant of the method according to the present invention for manufacturing a diaphragm having hollow support structures and a hard mask layer as the cover layer;

### DETAILED DESCRIPTION

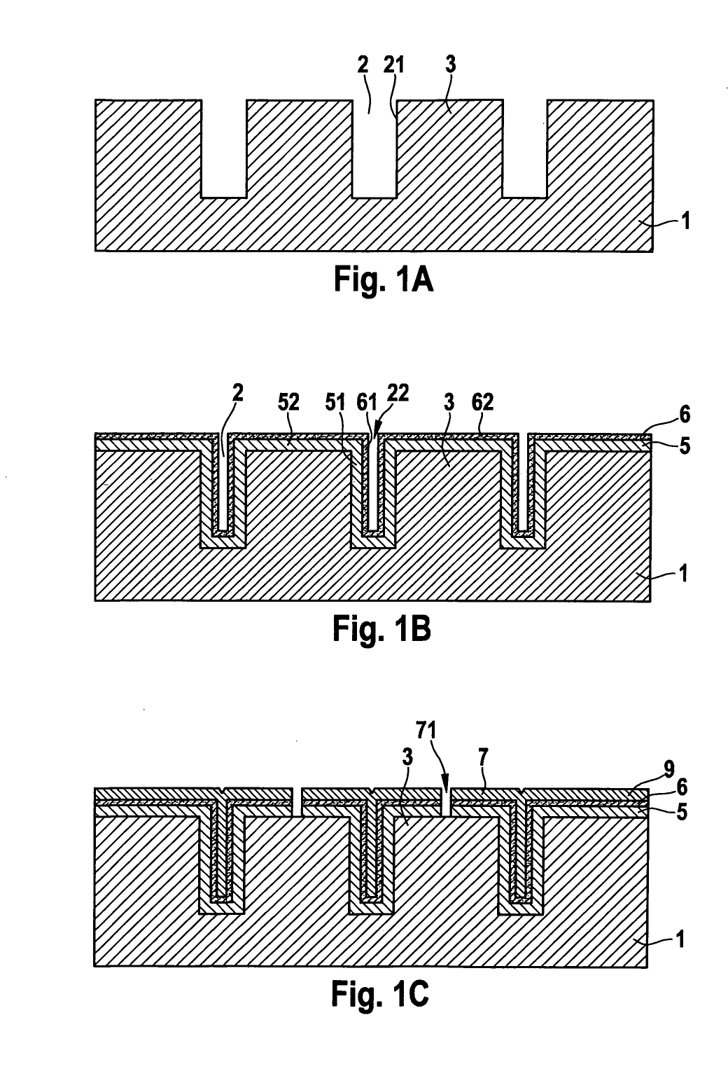

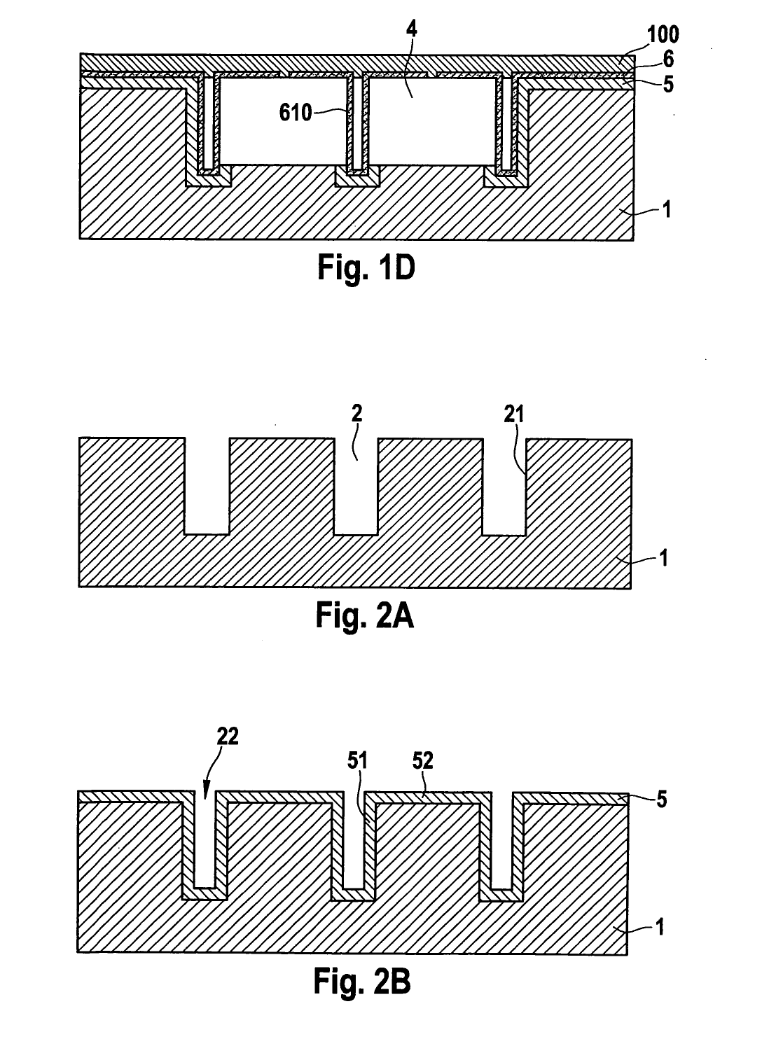

FIGS. 1A through 1D show a first exemplary embodiment of the method according to the present invention for manufacturing a diaphragm on a semiconductor substrate. Deep trenches (2) are introduced into semiconductor substrate (1) in the area of the later cavity, which may be with the aid of a photoresist mask and an etching step. The design of trenches (2) in the form of oblong holes is advantageous. However, other shapes (round or square columns, short form, etc.) are conceivable. The trench shape also determines the shape of the later support structures of the diaphragm and the required thickness of the later sealing layer.

Trenches (2) may be etched with the aid of a lacquer or hard mask layer, which is applied to substrate (1) and subsequently structured (not shown here).

FIG. 1A shows semiconductor substrate (1), in which deep trenches (2) may be produced in the area of the later cavity. Silicon may be used as the semiconductor substrate. Webs (3) made of silicon, in which cavities are produced later, have resulted due to the etching of trenches (2). The illustration of trenches (2) is solely schematic. Their number, shape, and distribution are tailored to the particular application. To produce support structures (610) for the later diaphragm, a semiconductor substrate (5) is subsequently deposited on the exposed areas of trenches (2). Semiconductor material (5) is also deposited on the webs (3). Polycrystalline silicon may be used as the semiconductor material, which is deposited as uniformly as possible on substrate (1) using a suitable deposition method, such as an LPCVD method. The layer thickness of polysilicon (5) is determined in such a way that trenches (2) are not completely filled up, but rather only the diameter of trench openings (22) is reduced. Silicon surface (5) is subsequently oxidized with the aid of a thermal oxidation method, so that a thin silicon oxide layer (6) is produced on entire silicon surface (5). Hollow oxide columns (610) thus arise within the trenches, which later form the support structures for diaphragm (100). This is illustrated in FIG. 1B.

As shown in FIG. 1C, a further layer (9), which may be polycrystalline silicon, is deposited on silicon oxide layer (6) in the following method step. This layer (9) is used as a sacrificial layer and closes existing trench openings (22), so that a closed surface having little topology results. The closed surface allows a subsequent photolithography step, by which openings may be introduced into polycrystalline silicon layer (9) and oxide layer (6) lying underneath, which may be done using a plasma process. Openings (71) in oxide layer (6) used as a cover layer (7) represent access openings for the subsequent etching of silicon substrate (1).

The diameter of access openings (71) may be kept smaller than the width of trench openings (22) after oxidation of polysilicon layer (5) to keep the required thickness of sealing layer (100) as low as possible. The number, configuration, and shape of access openings (71) may be selected freely in principle. They are oriented in particular to the particular spatial extent of the cavities to be produced.

Subsequently, silicon substrate (1) may be etched back in webs (3) through access openings (71) using a suitable method to form a cavity (4). An isotropic etching method may be selected, which is selective to the silicon oxide. In particular, gas-phase etching (GP etching, e.g., using ClF₃) comes into consideration. In this etching procedure, polycrystalline silicon (52) below silicon oxide cover layer (62) is also removed. Finally, webs (3) are hollowed out from the inside by etching back bulk silicon (1). Hollow spaces (4), which form the desired cavities, thus result. They are laterally delimited by oxide layer (61) produced in trenches (2). Their depth is less than the depth of produced trenches (2).

As shown in FIG. 1D, oxide columns (610) produced in trenches (2) may be configured in such a way that they project deeper into semiconductor substrate (2) than cavities (4) produced by etching. It is thus ensured that thin oxide columns (610) used as support structures offer sufficient stability to diaphragm (100).

Sacrificial layer (9) made of polycrystalline silicon may also be removed during the etching step, the polycrystalline silicon may be completely removed from trenches (2).

In the following method step, a sealing layer (100) is deposited in the area of the diaphragm to close access and trench openings (71, 22). This layer (100) typically forms the actual diaphragm, on which further functional layers may be processed. It may be made of a dielectric material, such as silicon oxide, silicon nitride, or a combination of these two materials. During deposition of sealing layer (100), the dielectric material is only deposited in opening area (22) of trenches (2) and/or access openings (71), without trenches (2) and/or cavities (4) being filled up. Optionally, sealing layer (100) may be planarized using known methods (e.g., CMP, plasma process). The required thickness of sealing layer (100) is strongly dependent on the opening widths to be bridged. It becomes increasingly more difficult to close openings as they become wider. Firstly, depressions form within the sealing layer over the openings, which result in an uneven surface. Because such irregularities may impair the function of the functional elements situated on the diaphragm, a thicker diaphragm layer is needed to compensate for the depressions. Furthermore, in the event of an opening width which is too wide, the deposited material may also enter the actual trenches or gaps to be covered, which may also have undesired effects.

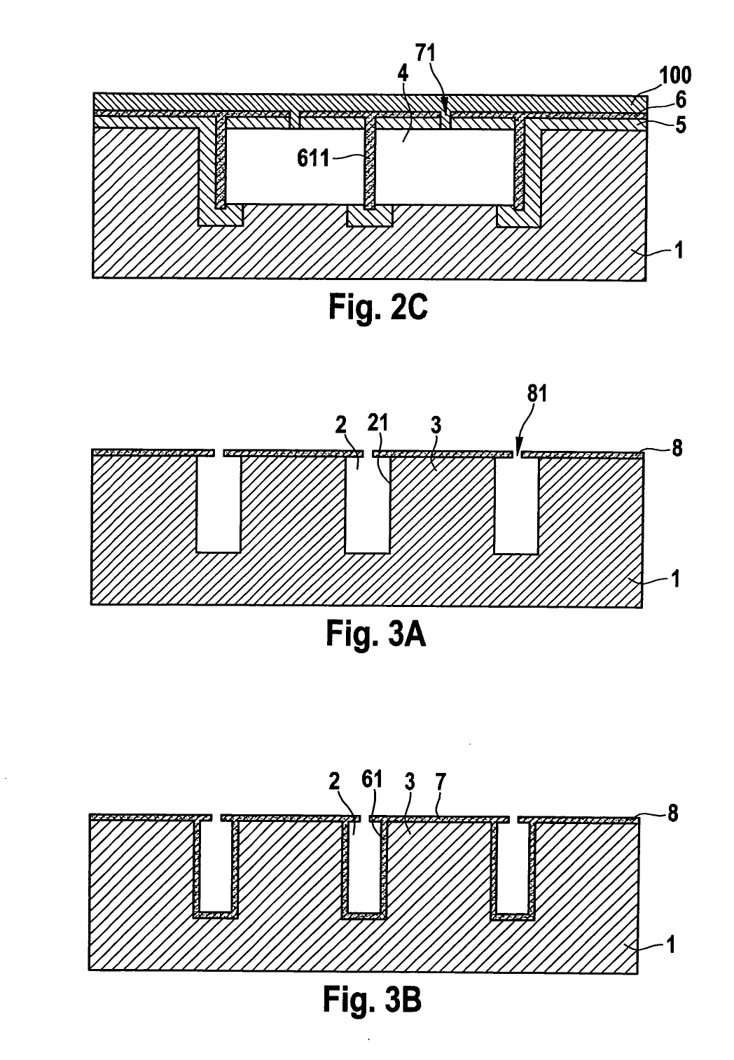

In the following, an alternative process control of the method according to the present invention is explained in greater detail on the basis of FIGS. 2A through 2C. The process runs essentially similarly to the first method variation shown in FIGS. 1A through 1D, thin solid oxide columns (611) being produced instead of hollow columns, however. Because of completely closed trenches (2), the deposition of a sacrificial layer (9) required in the first method variant is no longer necessary here.

Similarly to FIG. 1A, FIG. 2A shows a silicon substrate (1), in which three trenches (2) have been produced in preceding steps. In the subsequent method steps, a polycrystalline silicon layer (5) is deposited and subsequently oxidized similarly to the first process control shown in FIGS. 1A through 1D. Deposited silicon layer (5) is thicker, in contrast to the semiconductor layer shown in FIG. 1B, so that trenches (2) are constricted down to a narrow gap. A gap having a high aspect ratio may result, whose depth essentially corresponds to the trench depth. This is shown in FIG. 2B.

Trenches (2) are completely filled up with silicon oxide by the subsequent thermal oxidation, so that solid oxide columns (611) arise within trenches (2), which later form the support structures for diaphragm (100). Because the surface is completely closed, the lithography to produce access openings (71) for the etching of cavities (4) may be performed without a further sacrificial layer (9).

A method similar to the first variant (FIGS. 1C through 1D) is used to implement hollow spaces (4) between trenches (2), which form the later cavities. The diaphragm is also manufactured here using gas-phase etching (GPE) and application of a dielectric sealing layer (100).

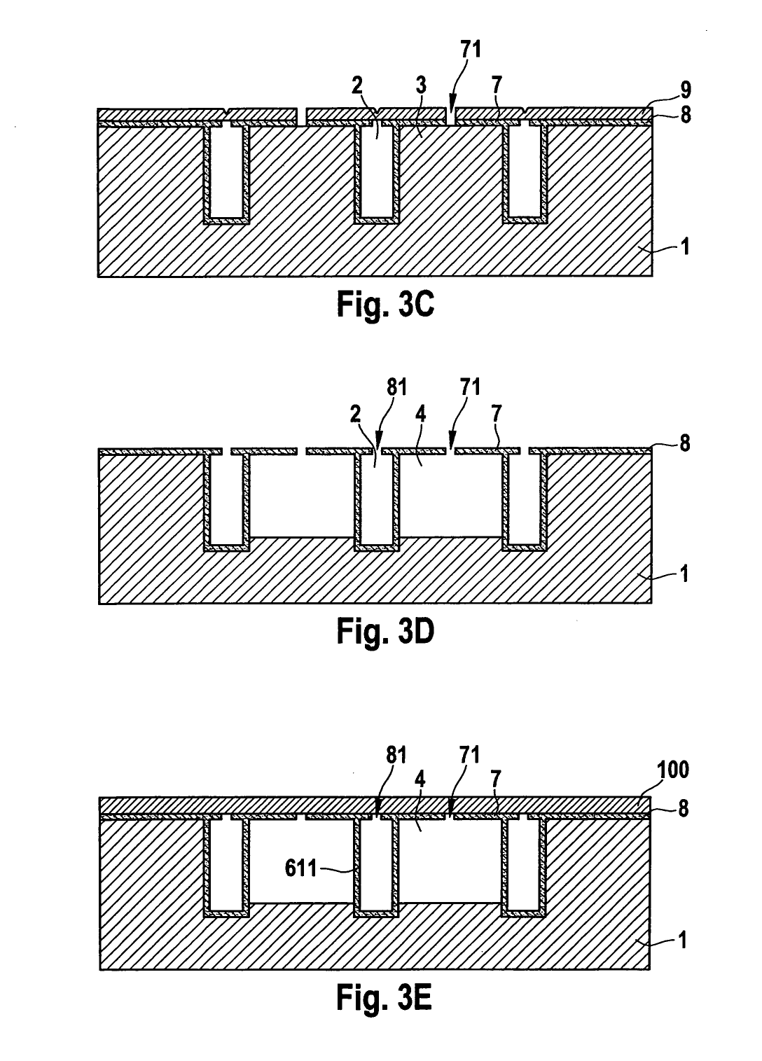

FIGS. 3A through 3E show a further variant of the method according to the present invention. In contrast to the two method sequences shown in FIGS. 1A through 1D and 2A through 2C, oxide columns (61) used as support structures are produced by direct oxidation of silicon substrate (1) in trenches (2).

For this purpose, in a first method step, trenches (2) are etched in silicon substrate (1). As shown in FIG. 3A, a hard mask layer (8) is used for this purpose, which is deposited on silicon substrate (1) and subsequently structured in a known way. Openings (81) are produced in hard mask layer (8), through which trenches (2) are subsequently etched. For example, thermal or PECVD oxide is suitable as the hard mask material. In contrast to the method variants already described above, hard mask (8) is not removed after the etching of trench (2), but rather is subsequently used as a cover layer (7) for implementing cavities (4). This method variant has the advantage that the opening widths in hard mask (8) are significantly less than those of deep trenches (2) in silicon substrate (1) thus produced. The later sealing of these openings (81) is thus made easier.

To implement oxide columns (61) supporting later diaphragm (100), side walls (21) of trenches (2) are completely covered with oxide (61) by thermal oxidation. Hollow oxide columns (610) resulting in trenches (2) later form the support structures for diaphragm (100). This is shown in FIG. 3B.

Similarly to the first variant (FIGS. 1A through 1D), a sacrificial layer (9) is required to cover trenches (2) against the photoresist before the lithography step performed to produce access openings (71). Polycrystalline silicon may be used as the material. Access openings (71) are subsequently produced in hard mask (8) used as a cover layer (7) via photolithography. As shown in FIG. 3C, access openings (71) have essentially the same opening width as openings (81) over trenches (2) implemented in hard mask (8). Subsequently, similarly to the method variants shown in FIGS. 1A through 1D and 2A through 2C, cavities (4) are produced in webs (3) using gas-phase etching. FIG. 3D shows finished cavities (4). The deposition of sealing layer (100) to close openings (71, 81) in hard mask (8) and produce a diaphragm is also performed in the way already described.

As shown in FIGS. 1D, 2C, and 3E, deposited sealing layer (100) spans cavities (4) and is supported by support structures (610, 611), which are formed by thin hollow or solid oxide columns. Sealing layer (100) forms the base structure of the actual diaphragm, on which further functional layers and/or structures may be produced depending on the application. Because openings (71, 81) to be closed have very small opening widths according to the present invention, deposited sealing layer (100) is particularly thin in comparison to conventional diaphragms.

The number and distribution of access openings (71) may be selected freely in principle in all variants of the method according to the present invention. This is also true for the shape of these openings (71). These parameters may be oriented according to the particular spatial extent of the cavities to be produced. In particular, for example, elongated access openings or access openings (71) enclosing one or more trenches (2) are also conceivable. The number, shape, and configuration of cavities (4) may also be varied arbitrarily. However, the cavities are designed above all with the goal of thermally insulating diaphragm (100) from substrate (1) as well as possible. Therefore, designs of support elements (61) and cavities (4) which have a low density of support elements may be used. Simultaneously, particularly narrow trench openings (22) are produced according to the exemplary embodiments and/or exemplary methods of the present invention, to be able to design sealing layer (100) as thin as possible.

1-15. (canceled)

16. A method for manufacturing a diaphragm on a semiconductor substrate, the method comprising:
a) providing a semiconductor substrate;
b) producing trenches in the semiconductor substrate, wherein webs made of the semiconductor substrate remain between the trenches;
c) producing an oxide layer on walls of the trenches using a thermal oxidation process;
d) producing access openings in a cover layer produced in a preceding process on the semiconductor substrate to expose the semiconductor substrate in an area of the webs;
e) isotropically etching the semiconductor substrate exposed in d) using a process selective to the oxide layer and to the cover layer, wherein at least one cavity is produced in the webs below the cover layer, which is laterally delimited by the oxide layer of at least one trench; and
f) depositing a sealing layer to close the access openings in the cover layer.

17. The method of claim 16, wherein the oxide layer is produced in c) in that a semiconductor layer is deposited on the walls of the trenches and subsequently thermally oxidized, a diameter of the trench openings being reduced and an aspect ratio of the trenches being increased upon deposition of the semiconductor layer.

18. The method of claim 17, wherein the semiconductor layer is also deposited on a surface of the semiconductor substrate in an area of the webs and subsequently oxidized, the oxidized semiconductor layer subsequently forming the cover layer.

19. The method of claim 17, wherein the trenches are constricted upon deposition of the semiconductor layer, so that a gap having a small opening width remains in each of the trenches, a hollow oxide column being produced in an interior of each of the trenches upon a subsequent oxidation of the semiconductor layer.

20. The method of claim 17, wherein the trenches are constricted upon deposition of the semiconductor layer, so that a narrow gap remains in each of the trenches, which is filled completely with oxide upon a subsequent oxidation of the semiconductor layer, a thin solid oxide column being produced in an interior of each of the trenches.

21. The method of claim 17, wherein the semiconductor layer includes one of polysilicon and germanium.

22. The method of claim 21, wherein the one of the polysilicon and the germanium is deposited using an LPCVD process.

23. The method of claim 15, wherein the trenches are produced in b) using a hard mask that subsequently forms the cover layer.

24. The method of claim 23, wherein the oxide layer is produced in c) in that the semiconductor substrate on the walls of the trenches is thermally oxidized.

25. The method of claim 16, wherein the access openings are produced having an opening width essentially equal to that of the trench openings in d).

26. The method of claim 19, wherein hollow oxide columns are closed upon a depositing of the sealing layer in f).

27. The method of claim 17, wherein, after the production of the oxide layer in c) and before the production of the access openings in d), a sacrificial layer is deposited, the trenches are sealed, and the sacrificial layer is removed again upon the isotropic etching in e).

28. A micromechanical component, comprising:
a diaphragm that is made by performing the following:
a) providing a semiconductor substrate;
b) producing trenches in the semiconductor substrate, wherein webs made of the semiconductor substrate remain between the trenches;
c) producing an oxide layer on walls of the trenches using a thermal oxidation process;
d) producing access openings in a cover layer produced in a preceding process on the semiconductor substrate to expose the semiconductor substrate in an area of the webs;
e) isotropically etching the semiconductor substrate exposed in d) using a process selective to the oxide layer and to the cover layer, wherein at least one cavity is produced in the webs below the cover layer, which is laterally delimited by the oxide layer of at least one trench; and
f) depositing a sealing layer to close the access openings in the cover layer;
wherein the diaphragm spans at least one cavity implemented in the semiconductor substrate of the micromechanical component, wherein the diaphragm is supported by at least one thin support structure situated in an area of the cavity, and wherein the support structure is configured as one of a hollow and a solid thin oxide column formed by thermal oxidation of the semiconductor.

29. The micromechanical component of claim 28, wherein the diaphragm is situated in an area of the cavity on a cover layer that directly delimits the cavity on top, and wherein the cover layer and the support structure form a joint oxide layer.

30. The micromechanical component of claim 28, wherein the diaphragm is situated in an area of the cavity on a hard mask layer that directly delimits the cavity on top.
